(19) United States
(12) Patent Application Publication
(10) Pub. No.: US 2019/0055641 A1
(43) Pub. Date: Feb. 21, 2019

(54) VAPOR DEPOSITION MACHINE

(71) Applicant: Wuhan China Star Optoelectronics Semiconductor Display Technology Co., Ltd., Wuhan, Hubei (CN)

(72) Inventors: Qian JIANG, Wuhan, Hubei (CN); Yungsheng CHEN, Wuhan, Hubei (CN)

(21) Appl. No.: 15/579,625

(22) PCT Filed: Oct. 19, 2017
(86) PCT No.: PCT/CN2017/106788

§ 371 Date: Dec. 5, 2017

(30) Foreign Application Priority Data
Aug. 16, 2017 (CN) 201710699880.X

(51) Int. Cl. C23C 14/24; C23C 14/04; C23C 14/02

(52) U.S. Cl. CPC C23C 14/24; C23C 14/021; C23C 14/042

(57) ABSTRACT

A vapor deposition machine includes at least two substrate cleaning units, an atmospheric pressure chamber, and a vacuum chamber assembly. The atmospheric pressure chamber is disposed between the substrate cleaning unit and the vacuum chamber assembly. The atmospheric pressure chamber includes a compensation and testing chamber for at least one metal mask at atmospheric pressure and a receiving chamber for the metal mask at atmospheric pressure.

### FIELD OF THE INVENTION

The present disclosure relates to the field of manufacturing devices, and more particularly to a vapor deposition machine.

### BACKGROUND OF THE INVENTION

Organic light emitting diode (OLED) devices have wide applications in flat panel displays due to their advantages of being self-luminous, all solid-state, having wide viewing angles, fast response times, etc., and are even considered as a new generation of flat panel displays after liquid crystal displays (LCD) and plasma display panels (PDP).

Coating technology can be broadly divided into physical vapor deposition and chemical vapor deposition. The former mainly performs a thin film deposition using physical phenomenon, and the latter mainly performs the thin film deposition using chemical reactions. The physical vapor deposition is currently dominated by evaporation and sputtering technologies. Common to the two technologies is to perform the thin film deposition using physical phenomenon. In the case of the evaporation technology, principle is mainly to perform the thin film deposition by heating an object to be deposited and using a saturated vapor pressure of the object at a high temperature (near a melting point of the object).

Evaporation technology is widely used. For example, an organic electroluminescent device is one mainstream display. An organic layer of the organic electroluminescent device can be formed by evaporation technology. However, existing evaporation technology still has difficulty in fabricating large area devices due to material degradation due to high temperatures, uneven thickness of a vapor deposition film, and a low material utilization.

An OLED film is formed using a vacuum evaporation technology, where organic/metal material is heated in a vacuum environment, and an organic/metal film having certain shape is formed on a surface of a substrate using a patterned metal mask. After continuous thin film depositions of multiple materials, an OLED structure with multiple layers of thin films can be formed.

Under normal circumstances, a vacuum vapor deposition machine has five kinds of operations:

(1) Machine maintenance (including filling material, a replacement of an attachment-resisting plate, a replacement of a crystal oscillating wafer, etc.)

(2) Correction operations of film thickness.

(3) Production of OLED devices.

(4) Compensation and debugging operation of fine masks.

(5) Production of products.

In operations 3 and 5, a machine can be automatically executed after setting a process menu. Operations 1, 2, and 4 require a manual operation of a worker. Effective operations of a production line of a vapor deposition machine (production of OLED device and production of product) and other operations (the operations 1, 2, and 4) are in conflict, and the longer the other operations are, the shorter the effective operations are.

Operation 4, compensation and debugging operation of fine masks, is as follows.

In order to manufacture a color display panel, an array substrate in a vacuum vapor deposition process needs to be used. Anode patterns corresponding to red (R), green (G), and blue (B) subpixels are exposed outside a surface of the array substrate. In addition, there is an insulating layer between each subpixel and adjacent subpixel.

A light-emitting layer of the OLED is deposited using a fine mask. Each of the subpixels, usually, red (R), green (G), and blue (B) subpixels, requires the fine mask. The compensation and debugging operation of fine mask can make a position of a film-forming pattern cover an anode of the subpixel, and the anode is disposed in a center of the film-forming pattern after a thin film deposition using the fine mask to avoid color mixing.

However, existing compensation and debugging operation of a fine mask has the following three disadvantages.

(1) The compensating method of the metal mask occupies a coating chamber of a vapor deposition equipment. Usually, there are 3-5 fine pattern film-forming chambers for each vapor deposition equipment. The metal mask is debugged by the compensation method such that an entire production line of the vacuum vapor deposition process cannot be normally operated, the machine must wait for the debugging operation of the metal mask, and then starts the normal production of the product.

(2) The compensation method of the metal mask must use evaporation film-forming material (usually organic material), and each mask must debug 3-5 substrates to complete the debugging operation. Usually, each product has three sets of the masks, each set of the masks has 3-5 masks, each product has a total of 9 to 15 fine metal masks. Therefore, each product requires debugging 27 to 75 substrates. Evaporation film-forming material is expensive, and each new product requires a lot of evaporation film-forming material.

(3) Speed of the compensation method of the metal mask is slow due to each metal mask needs to go through the processes such as material heating and rate stabilization, film deposition, and film pattern measurement processes. Vapor deposition rate is usually 0.5 to 2 Å/s, a film thickness ranges 500 to 1500 Å, and a monolithic glass film is formed at 15 min. Considering the amount of glass (27-75) in the compensation and debugging operation, debugging the masks of each new product needs 400 to 1000 min.

FIG. 1 is a schematic structural view of a fine metal mask compensation device disclosed in reference 1, “A Fine Metal Mask Compensation Method and Device.” The fine metal mask compensation device includes at least two substrate cleaning units 1, a main vacuum chamber 2, and an auxiliary vacuum chamber 3. The main vacuum chamber includes five vacuum vapor deposition chambers and a metal mask compensation and debugging chamber 4. The metal mask compensation and debugging chamber is in a vacuum environment.

The reference 1 has a partial modification to a vapor deposition machine to perform a metal mask compensation and test using a special light source, but the modified machine has the following disadvantages.

(1) Wasting of vacuum resources: In the vapor deposition machine of the reference 1, compensation and debugging operation of metal masks does not require to deposit a thin film, therefore, the operation needs not to be performed in a vacuum environment.

(2) Long transmission time of the substrate: When the substrate is transported from the atmospheric environment to the vacuum environment or from the vacuum environment to the atmospheric environment, the substrate must go through a certain chamber. Therefore, the substrate entering the chamber, breaking vacuum, removing the substrate, vacuuming, or waiting for the next substrate entering the chamber, etc., delays the effective operation of the vapor deposition machine.

Therefore, the existing vapor deposition machine is not only time-consuming, affecting the normal working time of the machine, reducing the efficiency of the whole process, wasting raw material, but also increases operation costs.

### SUMMARY OF INVENTION

The present disclosure provides a vapor deposition machine to solve the problem of long conversion time between a normal operation and a metal mask compensation and test of the existing vapor deposition machine.

To achieve the above object, an embodiment of the present disclosure provides a vapor deposition machine including:

at least two substrate cleaning units;

an atmospheric pressure chamber including a compensation and testing chamber for at least one metal mask at atmospheric pressure and a receiving chamber for the metal mask at atmospheric pressure, the compensation and testing chamber configured to receive the metal mask, an alignment system configured to align at least one substrate, and a light source disposed on a bottom part of the compensation and testing chamber; and

a vacuum chamber assembly, wherein the atmospheric pressure chamber is disposed between the substrate cleaning unit and the vacuum chamber assembly.

In an embodiment of the present disclosure, the atmospheric pressure chamber further includes a first atmospheric pressure chamber, a second atmospheric pressure chamber, a third atmospheric pressure chamber, and a fourth atmospheric pressure chamber, the first atmospheric pressure chamber is configured to bake the substrate, the second atmospheric pressure chamber is configured to cool the substrate, the third atmospheric pressure chamber is configured to turn over the substrate, the fourth atmospheric pressure chamber is configured to temporarily receive the substrate, and the first atmospheric pressure chamber, the second atmospheric pressure chamber, and the third atmospheric pressure chamber receive at least twenty of the substrates.

In an embodiment of the present disclosure, the compensation and testing chamber is configured to receive one of the substrates and one of the metal masks during operation.

In an embodiment of the present disclosure, the compensation and testing chamber is configured in an atmospheric environment, and the compensation and testing chamber includes nitrogen gas or air.

In an embodiment of the present disclosure, the receiving chamber includes a first atmospheric pressure receiving chamber and a second atmospheric pressure receiving chamber, the first atmospheric pressure receiving chamber includes a substrate cassette configured to receive the at least one substrate, the second atmospheric pressure receiving chamber includes a metal mask cassette configured to receive the at least one metal mask.

In an embodiment of the present disclosure, the first atmospheric pressure receiving chamber is disposed above the second atmospheric pressure receiving chamber in a vertical direction, and the vapor deposition machine further includes a separating plate disposed between the first atmospheric pressure receiving chamber and the second atmospheric pressure receiving chamber.

In an embodiment of the present disclosure, the vapor deposition machine further includes a first connection chamber disposed between the atmospheric pressure chamber and the vacuum chamber assembly, the vapor deposition machine is configured to transfer the first connection chamber between an atmospheric environment and a vacuum environment, and the first connection chamber is configured to receive one of the substrates.

In an embodiment of the present disclosure, the vacuum chamber assembly includes a first vacuum chamber and a second vacuum chamber, the first vacuum chamber includes a first sub-chamber of the first vacuum chamber, a second sub-chamber of the first vacuum chamber, a third sub-chamber of the first vacuum chamber, a fourth sub-chamber of the first vacuum chamber, a fifth sub-chamber of the first vacuum chamber, and a sixth sub-chamber of the first vacuum chamber, the first sub-chamber of the first vacuum chamber is a plasma processing chamber, and the second sub-chamber of the first vacuum chamber, the third sub-chamber of the first vacuum chamber, and the fourth sub-chamber of the first vacuum chamber are each a common film-forming chamber.

In an embodiment of the present disclosure, the fifth sub-chamber of the first vacuum chamber is a fine patterned film-forming chamber, and the fifth sub-chamber of the first vacuum chamber is configured to receive one of the substrates and one of the metal masks during operation, the sixth sub-chamber of the first vacuum chamber includes a first vacuum receiving chamber and a second vacuum receiving chamber, the first vacuum receiving chamber is disposed above the second vacuum receiving in a vertical direction chamber, the first vacuum receiving chamber and the second vacuum receiving chamber are configured to receive the metal mask cassette, and a bottom layer of the second vacuum receiving chamber is configured to receive the substrate.

In an embodiment of the present disclosure, the second vacuum chamber includes a first sub-chamber of the second vacuum chamber, a second sub-chamber of the second vacuum chamber, a third sub-chamber of the second vacuum chamber, a fourth sub-chamber of the second vacuum chamber, a fifth sub-chamber of the second vacuum chamber, and a sixth sub-chamber of the second vacuum chamber, the first sub-chamber of the second vacuum chamber, the second sub-chamber of the second vacuum chamber, and the third sub-chamber of the second vacuum chamber are each a fine patterned film-forming chamber, and the sixth sub-chamber of the second vacuum chamber includes a third vacuum receiving chamber and a fourth vacuum receiving chamber, the third vacuum receiving chamber is disposed above the fourth vacuum receiving chamber in the vertical direction, and the third vacuum receiving chamber and the fourth vacuum receiving chamber are configured to receive the metal mask cassette.

An embodiment of the present disclosure further provides a vapor deposition machine including:
at least two substrate cleaning units;
an atmospheric pressure chamber including a compensation and testing chamber for at least one metal mask at atmospheric pressure and a receiving chamber for the metal mask at atmospheric pressure; and
a vacuum chamber assembly, wherein the atmospheric pressure chamber is disposed between the substrate cleaning unit and the vacuum chamber assembly.

In an embodiment of the present disclosure, the atmospheric pressure chamber further includes a first atmospheric pressure chamber, a second atmospheric pressure chamber, a third atmospheric pressure chamber, and a fourth atmospheric pressure chamber, the first atmospheric pressure chamber is configured to bake the substrate, the second atmospheric pressure chamber is configured to cool the substrate, the third atmospheric pressure chamber is configured to turn over the substrate, the fourth atmospheric pressure chamber is configured to temporarily receive the substrate, and the first atmospheric pressure chamber, the second atmospheric pressure chamber, and the third atmospheric pressure chamber receives at least twenty of the substrates.

In an embodiment of the present disclosure, the compensation and testing chamber is configured to receive one of the substrate and one of the metal mask during operation.

In an embodiment of the present disclosure, the compensation and testing chamber is configured in an atmospheric environment, and the compensation and testing chamber includes nitrogen gas or air.

In an embodiment of the present disclosure, the receiving chamber includes a first atmospheric pressure receiving chamber and a second atmospheric pressure receiving chamber, the first atmospheric pressure receiving chamber includes a substrate cassette configured to receive the at least one substrate, the second atmospheric pressure receiving chamber includes a metal mask cassette configured to receive the at least one metal mask.

In an embodiment of the present disclosure, the first atmospheric pressure receiving chamber is disposed above the second atmospheric pressure receiving chamber in a vertical direction, and the vapor deposition machine further includes a separating plate disposed between the first atmospheric pressure receiving chamber and the second atmospheric pressure receiving chamber.

In an embodiment of the present disclosure, the vapor deposition machine further includes a first connection chamber disposed between the atmospheric pressure chamber and the vacuum chamber assembly, the vapor deposition machine is configured to transfer the first connection chamber between an atmospheric environment and a vacuum environment, and the first connection chamber is configured to receive one of the substrate.

In an embodiment of the present disclosure, the vacuum chamber assembly includes a first vacuum chamber and a second vacuum chamber, the first vacuum chamber includes a first sub-chamber of the first vacuum chamber, a second sub-chamber of the first vacuum chamber, a third sub-chamber of the first vacuum chamber, a fourth sub-chamber of the first vacuum chamber, a fifth sub-chamber of the first vacuum chamber, and a sixth sub-chamber of the first vacuum chamber, the first sub-chamber of the first vacuum chamber is a plasma processing chamber, and the second sub-chamber of the first vacuum chamber, the third sub-chamber of the first vacuum chamber, and the fourth sub-chamber of the first vacuum chamber are each a common film-forming chamber.

In an embodiment of the present disclosure, the fifth sub-chamber of the first vacuum chamber is a fine patterned film-forming chamber, and the fifth sub-chamber of the first vacuum chamber is configured to receive one of the substrates and one of the metal masks during operation, the sixth sub-chamber of the first vacuum chamber includes a first vacuum receiving chamber and a second vacuum receiving chamber, the first vacuum receiving chamber is disposed above the second vacuum receiving in a vertical direction chamber, the first vacuum receiving chamber and the second vacuum receiving chamber are configured to receive the metal mask cassette, and a bottom layer of the second vacuum receiving chamber is configured to receive the substrate.

In an embodiment of the present disclosure, the second vacuum chamber includes a first sub-chamber of the second vacuum chamber, a second sub-chamber of the second vacuum chamber, a third sub-chamber of the second vacuum chamber, a fourth sub-chamber of the second vacuum chamber, a fifth sub-chamber of the second vacuum chamber, and a sixth sub-chamber of the second vacuum chamber, the first sub-chamber of the second vacuum chamber, the second sub-chamber of the second vacuum chamber, and the third sub-chamber of the second vacuum chamber are each a fine patterned film-forming chamber, and the sixth sub-chamber of the second vacuum chamber includes a third vacuum receiving chamber and a fourth vacuum receiving chamber, the third vacuum receiving chamber is disposed above the fourth vacuum receiving chamber in the vertical direction, and the third vacuum receiving chamber and the fourth vacuum receiving chamber are configured to receive the metal mask cassette.

Technical benefits of the embodiment of the present disclosure are disclosed. Compared to the existing technology, in the embodiment of the present disclosure, the atmospheric pressure chamber is disposed between the substrate cleaning unit and the vacuum chamber assembly, and the atmospheric chamber includes the compensation and testing chamber for the metal mask at atmospheric pressure and the receiving chamber for the metal mask at atmospheric pressure, such that the vapor deposition machine is converted between a normal operation and a metal mask compensation and test, the vapor deposition machine can directly perform the metal mask compensation and test in the atmospheric pressure chamber. The substrate does not need to wait for a certain chamber converted between the atmospheric environment and the vacuum environment, thus shortening the time of the metal mask compensation and test, increasing the effective operation time (production of OLED device and production of product) of the vapor deposition machine, improving the efficiency of the product line of the vapor deposition process, and saving vacuum resources of the machine.

The accompanying figures to be used in description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

### DESCRIPTION OF DRAWINGS

FIG. 1 is a schematic view illustrating a structure of a fine metal mask compensation device according to a reference 1.

FIG. 2 is a schematic view illustrating a structure of a vapor deposition machine according to an embodiment of the present disclosure.

FIG. 3 is a schematic view illustrating an operating time diagram of a vapor deposition machine according to existing technology.

FIG. 4 is a schematic view illustrating an operating time diagram of the fine metal mask compensation device according to reference 1.

FIG. 5 is a schematic view illustrating an operating time diagram of a vapor deposition machine according to an embodiment of the present disclosure.

### DETAILED DESCRIPTION OF PREFERRED EMBODIMENTS

The embodiments described herein with reference to the accompanying drawings are explanatory, illustrative, and used to generally understand the present disclosure. Furthermore, directional terms described by the present disclosure, such as top, bottom, front, rear, left, right, inner, outer, side, etc., are only directions by referring to the accompanying drawings, and thus the used terms are used only for the purpose of describing embodiments of the present disclosure and are not intended to be limiting of the present disclosure. In the drawings, modules with similar structures are labeled with the same reference number.

An existing vapor deposition machine is converted between the normal operation and the metal mask compensation and test, a certain chamber of the vapor deposition machine needs to be converted between the atmospheric environment and the vacuum environment, thus not only delaying the effective operation time of the vapor deposition machine but also wasting the vacuum resources of the machine. The present disclosure provides a vapor deposition machine capable of improving the defects.

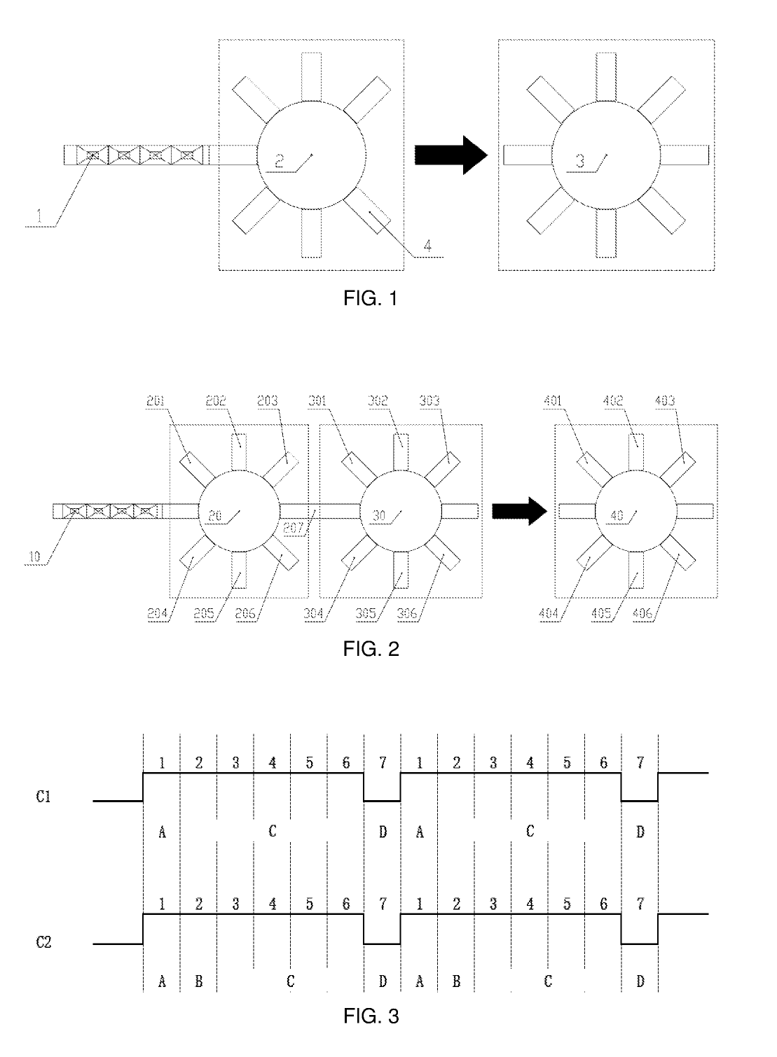

Refer to FIG. 2, a schematic view illustrating a structure of a vapor deposition machine according to an embodiment of the present disclosure is provided. The vapor deposition machine includes at least two substrate cleaning units 10, an atmospheric pressure chamber 20, and a vacuum chamber assembly.

Refer to FIG. 2, in the embodiment, a number of the substrate cleaning units 10 is four, and more substrate cleaning units 10 may be arranged according to a requirement in an actual production line.

The atmospheric pressure chamber 20 includes a compensation and testing chamber 205 for at least one metal mask at atmospheric pressure and a receiving chamber 206 for the metal mask at atmospheric pressure. The atmospheric pressure chamber 20 is disposed between the substrate cleaning unit 10 and the vacuum chamber assembly.

The compensation and testing chamber 205 is configured to receive one substrate and one metal mask during operation. The compensation and testing chamber 205 is configured to receive the metal mask, an alignment system configured to align at least one substrate, and a light source disposed on a bottom part of the compensation and testing chamber 205.

In addition, the compensation and testing chamber 205 is configured in an atmospheric environment, and the compensation and testing chamber 205 includes nitrogen gas or air.

The receiving chamber 206 includes a first atmospheric pressure receiving chamber and a second atmospheric pressure receiving chamber.

The first atmospheric pressure receiving chamber includes a substrate cassette configured to receive the at least one substrate. The substrate cassette is configured to receive one to five substrates or more of the substrates. The second atmospheric pressure receiving chamber includes a metal mask cassette configured to receive the at least one metal mask. The substrate cassette is configured to receive one to ten substrates or more of the substrates.

The first atmospheric pressure receiving chamber is disposed above the second atmospheric pressure receiving chamber in a vertical direction, and the vapor deposition machine further includes a separating plate disposed between the first atmospheric pressure receiving chamber and the second atmospheric pressure receiving chamber.

The atmospheric pressure chamber 20 further includes a first atmospheric pressure chamber 201, a second atmospheric pressure chamber 202, a third atmospheric pressure chamber 203, and a fourth atmospheric pressure chamber 204.

The first atmospheric pressure chamber 201 is configured to bake the substrate, the second atmospheric pressure chamber 202 is configured to cool the substrate, the third atmospheric pressure chamber 203 is configured to turn over the substrate, the fourth atmospheric pressure chamber 204 is configured to temporarily receive the substrate, and the first atmospheric pressure chamber 201, the second atmospheric pressure chamber 202, and the third atmospheric pressure chamber 203 receive at least twenty of the substrates.

The vapor deposition machine further includes a first connection chamber 207 disposed between the atmospheric pressure chamber 20 and the vacuum chamber assembly. The vapor deposition machine is configured to transfer the first connection chamber between an atmospheric environment and a vacuum environment, and the first connection chamber 207 is configured to receive one of the substrate.

The vacuum chamber assembly includes a first vacuum chamber 30 and a second vacuum chamber 40.

The first vacuum chamber 30 includes a first sub-chamber 301 of the first vacuum chamber 30, a second sub-chamber 302 of the first vacuum chamber 30, a third sub-chamber 303 of the first vacuum chamber 30, a fourth sub-chamber 304 of the first vacuum chamber 30, a fifth sub-chamber 305 of the first vacuum chamber 30, and a sixth sub-chamber 306 of the first vacuum chamber 30.

The first sub-chamber 301 of the first vacuum chamber 30 is a plasma processing chamber.

The second sub-chamber 302 of the first vacuum chamber 30, the third sub-chamber 303 of the first vacuum chamber 30, and the fourth sub-chamber 304 of the first vacuum chamber 30 are each a common film-forming chamber. A number of the common film-forming chambers can be 2 or 4, depending on a need of an OLED panel manufacturer.

The fifth sub-chamber 305 of the first vacuum chamber 30 is a fine patterned film-forming chamber, and the fifth sub-chamber 305 of the first vacuum chamber 30 is configured to receive one of the substrates and one of the metal masks during operation.

The sixth sub-chamber 306 of the first vacuum chamber 30 includes a first vacuum receiving chamber and a second vacuum receiving chamber. The first vacuum receiving chamber is disposed above the second vacuum receiving in a vertical direction chamber. The first vacuum receiving chamber and the second vacuum receiving chamber are configured to receive the metal mask cassette. A bottom layer of the second vacuum receiving chamber is configured to receive the substrate.

The second vacuum chamber 40 includes a first sub-chamber 401 of the second vacuum chamber 40, a second sub-chamber 402 of the second vacuum chamber 40, a third sub-chamber 403 of the second vacuum chamber 40, a fourth sub-chamber 404 of the second vacuum chamber 40, a fifth sub-chamber 405 of the second vacuum chamber 40, and a sixth sub-chamber 406 of the second vacuum chamber 40.

The first sub-chamber 401 of the second vacuum chamber 40, the second sub-chamber 402 of the second vacuum chamber 40, and the third sub-chamber 403 of the second vacuum chamber 40 are each a fine patterned film-forming chamber, and the sixth sub-chamber 406 of the second vacuum chamber 40 includes a third vacuum receiving chamber and a fourth vacuum receiving chamber. The third vacuum receiving chamber is disposed above the fourth vacuum receiving chamber in the vertical direction.

The third vacuum receiving chamber and the fourth vacuum receiving chamber are configured to receive the metal mask cassette.

The following will describe steps of the compensation and debugging operation of fine mask. The substrate using in the compensation and debugging operation of fine mask is a substrate A.

In step S110, the substrate A is cleaned in the substrate cleaning unit 10, baked in the first atmospheric pressure chamber 201, sent to the second atmospheric pressure chamber 202 for cooling, and then the substrate A is temporarily received in the second atmospheric pressure chamber 202.

In step S120, the first metal mask is moved into the compensation and testing chamber 205 from the receiving chamber 206.

In step S130, the substrate A is moved into the compensation and testing chamber 205 from the second atmospheric pressure chamber 202, and the substrate A is irradiated by the light source in the compensation and testing chamber 205.

In step S140, the substrate A irradiated by the light source is moved into the first atmospheric pressure receiving chamber, and the first metal mask is moved into the second atmospheric pressure receiving chamber.

In step S150, the second metal mask is moved into the compensation and testing chamber 205 from the receiving chamber 206, and the second substrate A is turned over using the atmospheric pressure chamber 203 and then moved into the receiving chamber 206. The substrate A is irradiated by the light source to perform a cyclic operation in the receiving chamber 206.

In step S160, a chamber door in the first atmospheric pressure receiving chamber is opened to remove a substrate measurement after the substrate A in the first atmospheric pressure receiving chamber is full.

The following will describe steps of production of product/OLED device. A product substrate is different from a mask debugging substrate. The product substrate is referred to as a substrate B herein.

In step S210, the substrate B is cleaned in the substrate cleaning unit 10, baked in the first atmospheric pressure chamber 201, sent to the second atmospheric pressure chamber 202 for cooling, and then temporarily received in the second atmospheric pressure chamber 202.

In step S220, the substrate B is removed from the second atmospheric pressure chamber 202, turned over using the third atmospheric pressure chamber 203, goes through the first connection chamber 207 converted between the atmospheric environment and the vacuum environment, and moved into the first sub-chamber 301 of the vacuum chamber 30 to perform a surface treatment.

In step S230, the metal masks in the first vacuum receiving chamber and the second vacuum receiving chamber of the sixth sub-chamber 306 of the first vacuum chamber 30 are moved into the second sub-chamber 302, the third sub-chamber 303, and the fourth sub-chamber 304 of the first vacuum chamber 30.

In step S240, the substrate B is removed from the first sub-chamber 301 of the first vacuum chamber 30, goes through the second sub-chamber 302, the third sub-chamber 303, and the fourth sub-chamber 304 of the first vacuum chamber 30, forms a film in the second sub-chamber 302, the third sub-chamber 303, and the fourth sub-chamber 304 of the first vacuum chamber 30, and then moved into the bottom layer of the second vacuum receiving chamber.

In step S250, the metal masks in the third vacuum receiving chamber and the fourth vacuum receiving chamber of the sixth sub-chamber 406 of the second vacuum chamber 40 are moved into the first sub-chamber 401, the second sub-chamber 402, the third sub-chamber 403, the fourth sub-chamber 404, and the fifth sub-chamber 405 of the second vacuum chamber 40.

In step S260, the substrate B is removed from the bottom layer of the second vacuum receiving chamber, goes through the first sub-chamber 401, the second sub-chamber 402, the third sub-chamber 403, the fourth sub-chamber 404, and the fifth sub-chamber 405 of the second vacuum chamber 40, forms a film in the first sub-chamber 401, the second sub-chamber 402, the third sub-chamber 403, the fourth sub-chamber 404, and the fifth sub-chamber 405 of the second vacuum chamber 40, and then moved into the bottom layer of the fourth vacuum receiving chamber.

It is to be understood that, if a number of a chamber of the vacuum chamber assembly is insufficient, the vacuum chamber assembly can be added in series to further increase the chambers.

FIG. 3 is a schematic view illustrating an operating time diagram of a vapor deposition machine according to an existing technology. In fact, an OLED production machine usually needs a continuous production for 144 hours (6 days), and then needs maintenance for 1 day. Refer to FIG. 3, C1 is a theoretical operating time diagram of the machine. Numbers 1 to 7 are the first day to the seventh day. Machine maintenance is performed on the seventh day (labeled D). After the machine maintenance, the machine usually needs to perform the vapor deposition and correct a film thickness (labeled A) using an ellipsometer. A correction time is related to a number of evaporation sources, and a correction of the film thickness usually requires at least one day.

The machine maintenance requires one day. Calculated in 28 days per month, a number of the effective operations of the vapor deposition machine per month is 4. Each effective operation time (production of product or production of OLED device) C requires 5 days, that is a total of 20 day/month. The following will analyze the machine operation based on the operation time.

When considering the compensation and debugging operation of the metal mask (labeled B), because the debugging operation of the metal mask occupies the fine film-forming chamber, production of product or production of an OLED device cannot be performed when the debugging operation of the metal mask is operated. In fact, time for a single effective operation is shorter. Time for the effective operation of the vapor deposition machine per month is 16 days, as shown in C2 of FIG. 3.

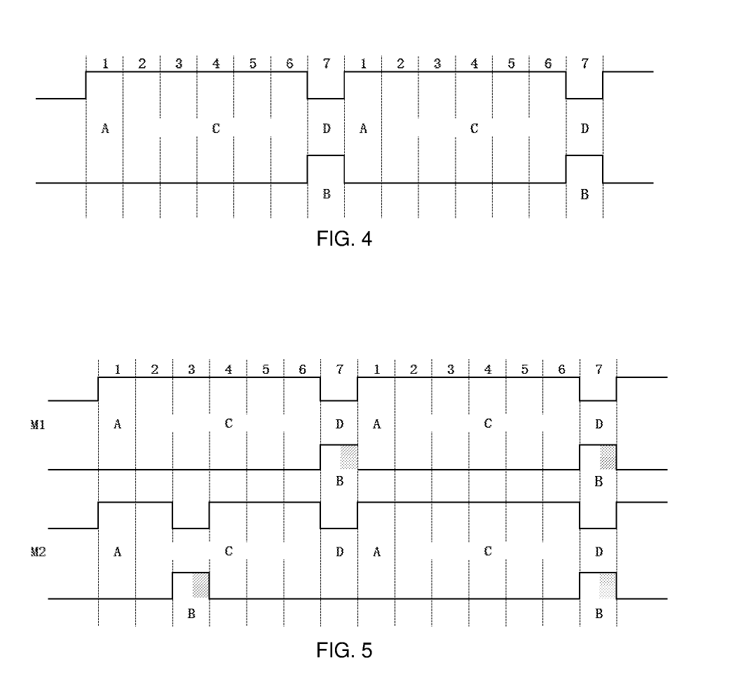

FIG. 4 is a schematic view illustrating an operating time diagram of the fine metal mask compensation device according to the reference 1, “A Fine Metal Mask Compensation Method and Device.”

The reference 1 discloses that photochromic delay material on a surface of a substrate is irradiated using a UV-ray passing through a fine mask, such that a pattern corresponding to the fine mask is left on the surface of the substrate. A compensation value of the fine mask is calculated by measuring a color-changed pattern on the substrate. In addition, in order to perform the compensation and debugging operation of the metal mask with high efficiency, a chamber is added to perform the compensation and debugging operation of the metal mask separately.

All film-forming chambers undergo a film thickness correction A to allow the production of product/OLED device directly. The compensation and debugging chamber for the metal mask is in wait state during the production of product/OLED device. When maintenance is performed after the film-forming chamber performs a continuous operation for 6 days, the compensation and debugging operation of the metal mask is performed simultaneously, thus extending time for the effective operation of the vapor deposition machine and improving machine utilization.

However, the compensation and debugging chamber for the metal mask and adjacent chamber are in a vacuum environment, the chambers must be equipped with a vacuum pump. The vacuum pump is a dry pump, a molecular pump, or a cold pump;

It is to be understood that, when the substrate in the compensation and debugging chamber for the metal mask is transported from the atmospheric environment to the vacuum environment or the vacuum environment to the atmospheric environment, the substrate must go through a certain chamber. Therefore, the substrate entering the chamber, breaking vacuum, removing the substrate, vacuuming, or waiting for the next substrate entering the chamber, etc., delays the effective operation of the vapor deposition machine and wastes the vacuum resources of the machine.

FIG. 5 is a schematic view illustrating an operating time diagram of a vapor deposition machine according to an embodiment of the present disclosure. When the operation of the vapor deposition machine is an operation M1 in FIG. 5, the six-day effective operation is performed after all the vapor deposition chambers have undergone the correction of the film thickness.

The compensation and testing chamber 205 is in a waiting state during the effective operation, and when the film-forming chamber performs maintenance, the compensation and debugging operation of the metal mask at atmospheric pressure is performed simultaneously.

Because of the presence of the receiving chamber 206, the substrate in the compensation and testing chamber can be rapidly moved into the receiving chamber 206 after being irradiated by the light source, and then the chamber door of the receiving chamber 206 is opened to remove the substrate directly for measurement.

Therefore, time consumed by the compensation and debugging operation of the metal mask in the operation M1 of FIG. 5 is less than time of a process in FIG. 4 (such as less than half of an original time). Refer to FIG. 4, in the operation M1, a width of an operation B is consumed time, a shadow is compressed time, and a white part is actual operation time of the operation B.

Refer to an operation M2 of FIG. 5, when the normal effective operation is stopped on the third day, the compensation and debugging operation of the metal mask is performed immediately, and then the normal effective operation is started. In addition, when the film-forming chamber performs maintenance, the compensation and debugging operation of the metal mask is performed simultaneously. Time of the compensation and debugging operation of the metal mask is greatly reduced, therefore, when a production line needs the compensation and debugging operation of the metal mask for emergency, the production line can quickly switch operations, thus shortening time of the compensation and debugging operation of the metal mask and extending the effective operation time of the vapor deposition machine.

In the embodiment of the present disclosure, the vapor deposition machine includes at least two substrate cleaning units, an atmospheric pressure chamber, and a vacuum chamber assembly. The atmospheric pressure chamber is disposed between the substrate cleaning unit and the vacuum chamber assembly, and the atmospheric chamber includes the compensation and testing chamber for the metal mask at atmospheric pressure and the receiving chamber for the metal mask at atmospheric pressure, such that the vapor deposition machine is converted between a normal operation and a metal mask compensation and test, the vapor deposition machine can directly perform the metal mask compensation and test in the atmospheric pressure chamber. The substrate does not need to wait for a certain chamber converted between the atmospheric environment and the vacuum environment, thus shortening the time of the metal mask compensation and test, increasing the effective operation time (production of OLED device and production of product) of the vapor deposition machine, improving efficiency of the product line of the vapor deposition process, and saving vacuum resources of the machine.

The present disclosure has been described with a preferred embodiment thereof. The preferred embodiment is not intended to limit the present disclosure, and it is understood that many changes and modifications to the described embodiment can be carried out without departing from the scope and the spirit of the invention that is intended to be limited only by the appended claims.

1. A vapor deposition machine, comprising:
at least two substrate cleaning units;
an atmospheric pressure chamber comprising a compensation and testing chamber for at least one metal mask at atmospheric pressure, and a receiving chamber for the metal mask at atmospheric pressure; the compensation and testing chamber configured to receive the metal mask, an alignment system, at least one substrate, and a fight source, the alignment system configured to align the at least one substrate, and the light source disposed on a bottom part of the compensation and testing chamber; and
a vacuum chamber assembly, wherein the atmospheric pressure chamber is disposed between the substrate cleaning units and the vacuum chamber assembly.

2. The vapor deposition machine according to claim 1, wherein the atmospheric pressure chamber further comprises a first atmospheric pressure chamber, a second atmospheric pressure chamber, a third atmospheric pressure chamber, and a fourth atmospheric pressure chamber; the first atmospheric pressure chamber is configured to bake the substrate, the second atmospheric pressure chamber is configured to cool the substrate, the third atmospheric pressure chamber is configured to turn over the substrate, the fourth atmospheric pressure chamber is configured to temporarily receive the substrate, and the first atmospheric pressure chamber, the second atmospheric pressure chamber, and the third atmospheric pressure chamber receive at least twenty of the substrates.

3. The vapor deposition machine according to claim 1, wherein the compensation and testing chamber is configured to receive one of the substrates and one of the metal masks during operation.

4. The vapor deposition machine according to claim 1, wherein the compensation and testing chamber is configured in an atmospheric environment, and the compensation and testing chamber comprises nitrogen gas or air.

5. The vapor deposition machine according to claim 1, wherein the receiving chamber comprises a first atmospheric pressure receiving chamber and a second atmospheric pressure receiving chamber, the first atmospheric pressure receiving chamber comprises a substrate cassette configured to receive the at least one substrate, and the second atmospheric pressure receiving chamber comprises a metal mask cassette configured to receive the at least one metal mask.

6. The vapor deposition machine according to claim 5, wherein the first atmospheric pressure receiving chamber is disposed above the second atmospheric pressure receiving chamber in a vertical direction, and the vapor deposition machine further comprises a separating plate disposed between the first atmospheric pressure receiving chamber and the second atmospheric pressure receiving chamber.

7. The vapor deposition machine according to claim 1, further comprising a first connection chamber disposed between the atmospheric pressure chamber and the vacuum chamber assembly, the vapor deposition machine configured to transfer the first connection chamber between an atmospheric environment and a vacuum environment, and the first connection chamber configured to receive one of the substrate.

8. The vapor deposition machine according to claim 1, wherein the vacuum chamber assembly comprises a first vacuum chamber and a second vacuum chamber, the first vacuum chamber comprises a first sub-chamber of the first vacuum chamber, a second sub-chamber of the first vacuum chamber, a third sub-chamber of the first vacuum chamber, a fourth sub-chamber of the first vacuum chamber, a fifth sub-chamber of the first vacuum chamber, and a sixth sub-chamber of the first vacuum chamber, the first sub-chamber of the first vacuum chamber is a plasma processing chamber, and the second sub-chamber of the first vacuum chamber, the third sub-chamber of the first vacuum chamber, and the fourth sub-chamber of the first vacuum chamber are each a common film-forming chamber.

9. The vapor deposition machine according to claim 8, wherein the fifth sub-chamber of the first vacuum chamber is a fine patterned film-forming chamber, and the fifth sub-chamber of the first vacuum chamber is configured to receive one of the substrates and one of the metal masks during operation, the sixth sub-chamber of the first vacuum chamber comprises a first vacuum receiving chamber and a second vacuum receiving chamber, the first vacuum receiving chamber is disposed above the second vacuum receiving in a vertical direction chamber, the first vacuum receiving chamber and the second vacuum receiving chamber are configured to receive the metal mask cassette, and a bottom layer of the second vacuum receiving chamber is configured to receive the substrate.

10. The vapor deposition machine according to claim 8, wherein the second vacuum chamber comprises a first sub-chamber of the second vacuum chamber, a second sub-chamber of the second vacuum chamber, a third sub-chamber of the second vacuum chamber, a fourth sub-chamber of the second vacuum chamber, a fifth sub-chamber of the second vacuum chamber, and a sixth sub-chamber of the second vacuum chamber, the first sub-chamber of the second vacuum chamber, the second sub-chamber of the second vacuum chamber, and the third sub-chamber of the second vacuum chamber are each a fine patterned film-forming chamber, the sixth sub-chamber of the second vacuum chamber comprises a third vacuum receiving chamber and a fourth vacuum receiving chamber, the third vacuum receiving chamber is disposed above the fourth vacuum receiving chamber in the vertical direction, and the third vacuum receiving chamber and the fourth vacuum receiving chamber are configured to receive the metal mask cassette.

11. A vapor deposition machine, comprising:
at least two substrate cleaning units;
an atmospheric pressure chamber comprising a compensation and testing chamber for at least one metal mask at atmospheric pressure and a receiving chamber for the metal mask at atmospheric pressure; and
a vacuum chamber assembly, wherein the atmospheric pressure chamber is disposed between the substrate cleaning unit and the vacuum chamber assembly.

12. The vapor deposition machine according to claim 11, wherein the atmospheric pressure chamber further comprises a first atmospheric pressure chamber, a second atmospheric pressure chamber, a third atmospheric pressure chamber, and a fourth atmospheric pressure chamber, the first atmospheric pressure chamber is configured to bake the substrate, the second atmospheric pressure chamber is configured to cool the substrate, the third atmospheric pressure chamber is configured to turn over the substrate, the fourth atmospheric pressure chamber is configured to temporarily receive the substrate, and the first atmospheric pressure chamber, the second atmospheric pressure chamber, and the third atmospheric pressure chamber receive at least twenty of the substrates.

13. The vapor deposition machine according to claim 11, wherein the compensation and testing chamber is configured to receive one of the substrates and one of the metal masks during operation.

14. The vapor deposition machine according to claim 11, wherein the compensation and testing chamber is configured in an atmospheric environment, and the compensation and testing chamber comprises nitrogen gas or air.

15. The vapor deposition machine according to claim 11, wherein the receiving chamber comprises a first atmospheric pressure receiving chamber and a second atmospheric pressure receiving chamber, the first atmospheric pressure receiving chamber comprises a substrate cassette configured to receive the at least one substrate, the second atmospheric pressure receiving chamber comprises a metal mask cassette configured to receive the at least one metal mask.

16. The vapor deposition machine according to claim 15, wherein the first atmospheric pressure receiving chamber is disposed above the second atmospheric pressure receiving chamber in a vertical direction, and the vapor deposition machine further comprises a separating plate disposed between the first atmospheric pressure receiving chamber and the second atmospheric pressure receiving chamber.

17. The vapor deposition machine according to claim 11, further comprising a first connection chamber disposed between the atmospheric pressure chamber and the vacuum chamber assembly, the vapor deposition machine configured to transfer the first connection chamber between an atmospheric environment and a vacuum environment, and the first connection chamber configured to receive one of the substrates.

18. The vapor deposition machine according to claim 11, wherein the vacuum chamber assembly comprises a first vacuum chamber and a second vacuum chamber, the first vacuum chamber comprises a first sub-chamber of the first vacuum chamber, a second sub-chamber of the first vacuum chamber, a third sub-chamber of the first vacuum chamber, a fourth sub-chamber of the first vacuum chamber, a fifth sub-chamber of the first vacuum chamber, and a sixth sub-chamber of the first vacuum chamber, the first sub-chamber of the first vacuum chamber is a plasma processing chamber, and the second sub-chamber of the first vacuum chamber, the third sub-chamber of the first vacuum chamber, and the fourth sub-chamber of the first vacuum chamber are each a common film-forming chamber.

19. The vapor deposition machine according to claim 19, wherein the fifth sub-chamber of the first vacuum chamber is a fine patterned film-forming chamber, and the fifth sub-chamber of the first vacuum chamber is configured to receive one of the substrates and one of the metal masks during operation, the sixth sub-chamber of the first vacuum chamber comprises a first vacuum receiving chamber and a second vacuum receiving chamber, the first vacuum receiving chamber is disposed above the second vacuum receiving in a vertical direction chamber, the first vacuum receiving chamber and the second vacuum receiving chamber are configured to receive the metal mask cassette, and a bottom layer of the second vacuum receiving chamber is configured to receive the substrate.

20. The vapor deposition machine according to claim 19, wherein the second vacuum chamber comprises a first sub-chamber of the second vacuum chamber, a second sub-chamber of the second vacuum chamber, a third sub-chamber of the second vacuum chamber, a fourth sub-chamber of the second vacuum chamber, a fifth sub-chamber of the second vacuum chamber, and a sixth sub-chamber of the second vacuum chamber, the first sub-chamber of the second vacuum chamber, the second sub-chamber of the second vacuum chamber, and the third sub-chamber of the second vacuum chamber are each a fine patterned film-forming chamber, the sixth sub-chamber of the second vacuum chamber comprises a third vacuum receiving chamber and a fourth vacuum receiving chamber, the third vacuum receiving chamber is disposed above the fourth vacuum receiving chamber in the vertical direction, and the third vacuum receiving chamber and the fourth vacuum receiving chamber are configured to receive the metal mask cassette.
